(19) United States
(12) Patent Application Publication
(10) Pub. No.: US 2021/0191191 A1
(43) Pub. Date: Jun. 24, 2021

(54) ELECTRONIC DEVICE

(71) Applicant: Innolux Corporation, Miao-Li County (TW)

(72) Inventors: Satoru Takahashi, Miao-Li County (TW); Kazuto Jitsui, Miao-Li County (TW)

(73) Assignee: Innolux Corporation, Miao-Li County (TW)

(21) Appl. No.: 16/718,201

(22) Filed: Dec. 18, 2019

(51) Int. Cl. G02F 1/1335; H01L 27/32

(52) U.S. Cl. CPC G02F 1/133514; H01L 27/322; G02F 2001/134345; G02F 2201/123; H01L 27/3213

(57) ABSTRACT

An electronic device includes a display panel and a parallax barrier. The display panel includes a plurality of color sub-pixels of a first color, a second color, and a third color. The parallax barrier overlaps the display panel, wherein the parallax barrier includes a plurality of barrier units. A barrier unit of the first color overlaps at least a color sub-pixel of the second color and a color sub-pixel of the third color in a top view.

### BACKGROUND

### Field of the Disclosure

The disclosure is related to an electronic device, and particularly related to an electronic device with a display panel which can display multiple-view images.

### Description of Related Art

Recently, the electronic device which can have multiple-view image has been proposed. For example, the dual-view display panel may display two images at the same time for two users, and each user can see his own image. However, the interference between two images still exists.

### SUMMARY OF THE DISCLOSURE

The disclosure has proposed a parallax barrier used with a display panel for multiple views, in which the interference may be reduced.

In an embodiment, the disclosure provides an electronic device including a display panel and a parallax barrier. The display panel includes a plurality of color sub-pixels of a first color, a second color, and a third color. The parallax barrier overlaps the display panel in a normal direction of the display panel, wherein the parallax barrier includes a plurality of barrier units. A barrier unit of the first color overlaps at least a color sub-pixel of the second color and a color sub-pixel of the third color in a top view.

In an embodiment, the disclosure also provides an electronic device. The electronic device includes a display panel and a parallax barrier, the display panel includes a plurality of color sub-pixels of a first color, a second color, a third color, and a fourth color. The four colors are sequentially designated to the color sub-pixels. The parallax barrier is overlapping the display panel in a normal direction of the display panel. The parallax barrier includes a plurality of barrier units. A barrier unit of the first color overlaps three adjacent sub-pixels in the top view. And the color of the barrier unit is the same as a color of the middle sub-pixel.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and the description serve to explain the principles of the disclosure.

FIG. 1 is a drawing, schematically illustrating a viewing effect for two users on a display panel for multiple views, according to an embodiment of the disclosure.

FIG. 2 is a drawing, schematically illustrating a structure of an electronic device, according to an embodiment of the disclosure.

FIG. 3 is a drawing, schematically illustrating the implementation of the parallax barrier with respect to the display panel, according to an embodiment of the disclosure.

FIG. 4 is a drawing, schematically illustrating the viewing effect for the left-view image and the right-view image, according to an embodiment of the disclosure.

FIG. 5 is a drawing, schematically illustrating an effect with respect to the viewing angle for different distances d between the CF parallax layer and the CF layer, according to an embodiment of the disclosure.

FIG. 6 is a drawing, schematically illustrating the filtering effect from the color filter layer and the parallax barrier, according to an embodiment of the disclosure.

FIG. 7 to FIG. 11 are drawings, schematically illustrating the implementations of the parallax barrier with respect to the display panel, according to embodiments of the disclosure.

FIG. 12 to FIG. 13 are drawings, schematically illustrating structures of electronic device, according to embodiments of the disclosure.

### DESCRIPTION OF THE EMBODIMENTS

The electronic device of the present disclosure is described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments.

In addition, the drawings of different embodiments may use similar and/or corresponding numerals to denote similar and/or corresponding elements in order to clearly describe the present disclosure. However, the use of similar and/or corresponding numerals in the drawings of different embodiments does not suggest any correlation between different embodiments. In addition, in this specification, expressions such as “first material layer disposed on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer or section. Thus, a first element, component, region, layer, portion or section discussed below could be termed a second element, component, region, layer, portion or section without departing from the teachings of the present disclosure.

It should be understood that this description of the exemplary embodiments is intended to be read in conjunction with the accompanying drawings, which are to be considered part of the entire written description. The drawings are not drawn to scale. In addition, structures and devices are shown schematically in order to simplify the drawing.

The terms “about” and “substantially” typically mean +/−20% of the stated value, or +/−10% of the stated value, or +/−5% of the stated value, or +/−3% of the stated value, or +/−2% of the stated value, or +/−1% of the stated value and even or +/−0.5% of the stated value. The stated value of the present disclosure is an approximate value. When there is no specific description, the stated value includes the meaning of “about” or “substantially”.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In addition, in some embodiments of the present disclosure, terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

The disclosures provide a structure of an electronic device in which a parallax barrier is used with a display panel for multiple views. The parallax barrier includes a plurality of barrier units. The interference of two images for adjacent two views may be effectively reduced.

Multiple embodiments are provided for description but the disclosure is not just limited to the embodiments as provided. In addition, a suitable modification or combination between the embodiments may be done.

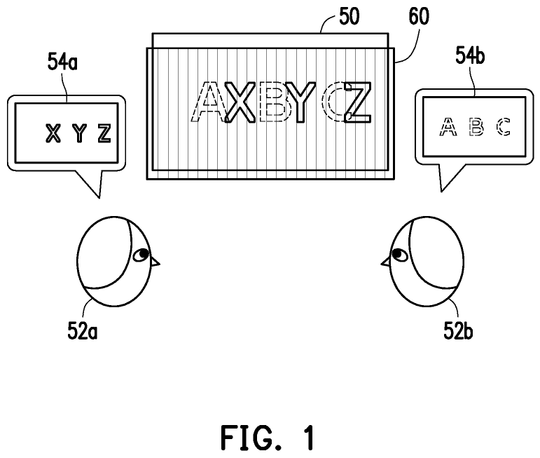

FIG. 1 is a drawing, schematically illustrating a viewing effect for two users of a display panel for multiple views, according to an embodiment of the disclosure. Referring to FIG. 1 as an example, an electronic device includes a display panel 50 to display a left-view image of “XYZ” and a right-view image of ABC. The parallax barrier 60 overlaps the display panel 50 in the normal direction of the display panel 50. Two users 52a, 52b are looking at the images displayed on the display panel 50. However, for the user 52a, the parallax barrier 60 would shield the image 54b of “ABC”. As a result, the user 52a ideally just views the image 54a of “XYZ” but not the image 54b of “ABC”. Likewise, for the user 52b, the parallax barrier 60 would shield the image 54a of “XYZ”. As a result, the user 52b ideally just views the image 54b of “ABC” but not the image 54a of “XYZ”.

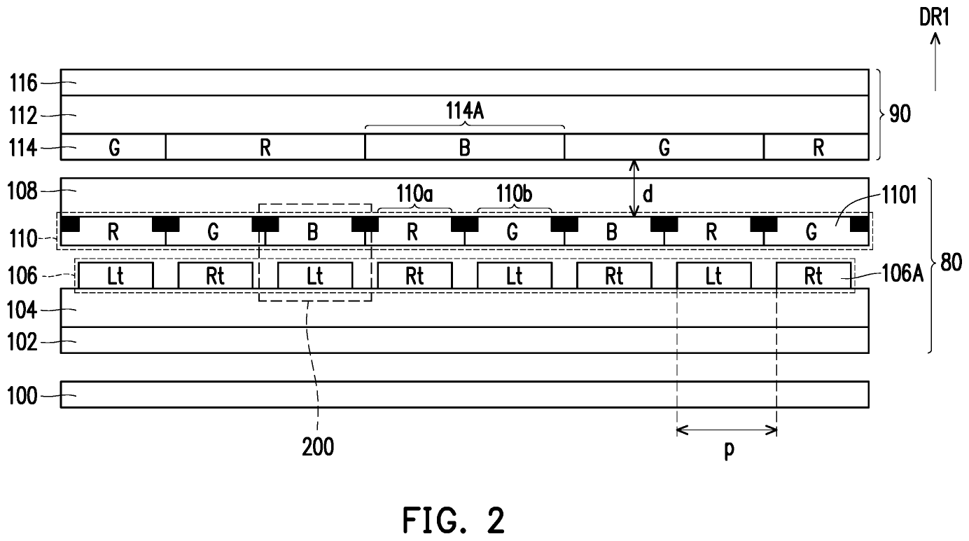

FIG. 2 is a drawing, schematically illustrating a structure of an electronic device, according to an embodiment of the disclosure. Referring to FIG. 2, an electronic device includes a display panel 80 a parallax barrier 90, and a backlight unit 100. The display panel 80 in an embodiment is a liquid crystal display (LCD) panel, wherein the backlight unit 100 is also implemented to provide the light source. It should be noted that the display panel 80 is not limited to the LCD panel. For examples, the display panel 80 may be an E-paper, organic light emitting diode (OLED) panel, mini-LED panel, micro-LED panel, any other suitable display, or the combination thereof. When the display panel can actively emit the color light, the backlight unit 100 can be omitted.

In the embodiment of LCD panel, the display panel 80 in detail may include a substrate 104 to implement a sub-pixel layer 106 disposed on one side of the substrate 104. The sub-pixel layer 106 includes a plurality of sub-pixels 106A to form a sub-pixel array with a plurality of sub-pixel rows. The sub-pixels 106A of the sub-pixel layer 106 in one of the sub-pixel rows are arranged to alternately display a first-view image such as left-view image (Lt) and a second-view image such as right-view image (Rt). It should be noted that in this embodiment, the sub-pixels 106A are arranged to alternately display a first-view image and a second-view image. But the disclosure is not limited thereto.

Since the embodiment is taking the LCD panel as an example, the CF layer 110 includes a plurality of color filter (CF) elements 1101. A color filter (CF) elements 1101 in a CF layer 110 corresponding to the sub-pixels 106A of the sub-pixel layer 106 are disposed on another substrate 108, but in some embodiments, the CF layer 110 and the sub-pixel layer are disposed on the same substrate 104. In the display panel 80, a color sub-pixel 200 includes one CF element 1101 of the CF layer 110 and one corresponding sub-pixel 106A of the sub-pixel layer 106. The black matrix, indicated by black area may be formed between the color sub-pixels 200. Similarly, the display panel 80 includes multiple color sub-pixels 200 to form a color sub-pixel array with a plurality of color sub-pixel rows.

It should be noted that the structure of the display panel 80 may be modified according to the actual design. The disclosure is not limited to a specific structure.

The parallax barrier 90 of the disclosure includes a CF parallax layer 114 disposed on a substrate 112. A polarizer layer 116 can be disposed on an opposite side of the substrate 112, but the position of the polarizer layer 116 is not limited thereto. The CF parallax layer 114 has multiple CF rows corresponding to the color sub-pixel rows of the display panel 80. The distance d between the CF parallax layer 114 and the CF layer 110 is the shortest distance between a surface of a CF parallax layer 114 to a surface of the CF layer 110. In the embodiment of the disclosure, the distance d between the CF parallax layer 114 and the CF layer 110 may be between 60 micrometers and 180 micrometers (60 micrometers≤d≤180 micrometers). In the parallax barrier 90, the CF parallax layer 114 includes a plurality of color filter (CF) rows, and a CF row has a plurality of barrier units 114A with colors of red (indicated by R), blue (indicated by B), and green (indicated by G) in a sequence, but the disclosure is not limited thereto.

As noted, a barrier unit 114A overlaps at least two adjacent color sub-pixels 200 in a normal direction DR1 of the display panel 80, wherein the at least two adjacent color sub-pixels 200 respectively correspond to the first-view image and the second-view image, and the barrier unit 114A and the two adjacent color sub-pixels 200 correspond to different colors respectively. For example, a red barrier unit 114A in a CF row overlaps a green color sub-pixel 200 and an adjacent blue color sub-pixel 200, and the two color sub-pixels 200 display a right-view image (Rt) and a left-view image (Lt) respectively. Likewise, the blue barrier unit 114A overlaps the red sub-pixels 200 and green color sub-pixels 200, and the green barrier unit 114A overlaps the blue sub-pixels 200 and red color sub-pixels 200.

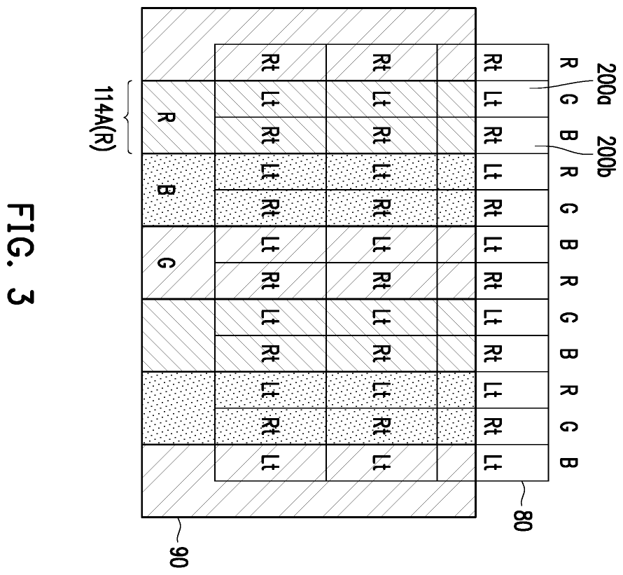

FIG. 3 is a drawing, schematically illustrating the implementation of the parallax barrier 90 with respect to the display panel 80, according to an embodiment of the disclosure. Referring to FIG. 3, as viewed in a normal direction of the display panel, the display panel 80 has a plurality of color sub-pixels 200a and sub-pixels 200b, which respectively display the left-view image (Lt) and the right-image (Rt) with the designated color of red, green or blue (indicated by R, G, or B).

The parallax barrier 90 overlaps the display panel 80 in a normal direction DR1 of the display panel 80. However, in order to show the arrangement of the color, the figure that parallax barrier 90 is shifted from display panel 80 in plane is just for easily understanding.

The rule as previously stated is applied to designate the color for the barrier units 114A, and it is not repeated herein.

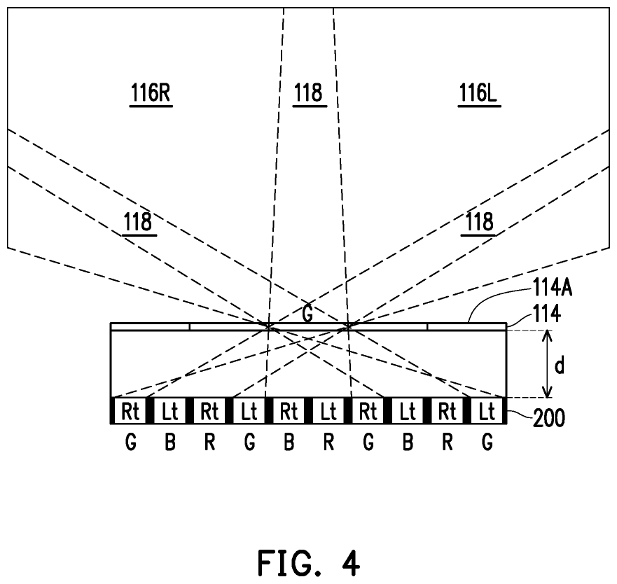

FIG. 4 is a drawing, schematically illustrating the viewing effect for the left-view image and the right-view image, according to an embodiment of the disclosure. Referring to FIG. 4, the effect of the parallax barrier including a plurality of barrier units 114A has been observed. Taking one green barrier unit 114A as an example, since the color light emitted from the red color sub-pixel 200 and the blue color sub-pixel 200 will be filtered by the green barrier unit 114A, the left viewing range 116R and a right viewing range 116L are set up that a viewer can see an image emitted from a green color sub-pixel 200, meanwhile a viewer in the interface region 118 may see a sufficiently dark image due to the filter effect of green barrier unit 114A. This would reduce the interference effect between the left-view image and the right-view image.

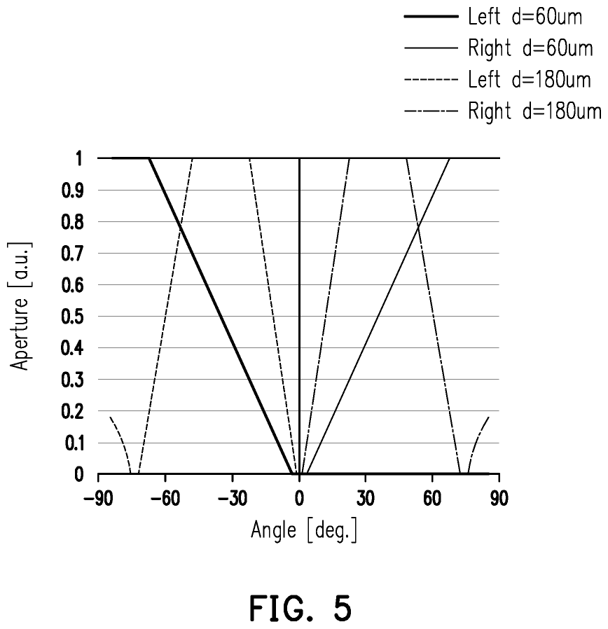

FIG. 5 is a drawing, schematically illustrating an effect with respect to the viewing angle for different distance d between the CF parallax layer and the CF layer, according to an embodiment of the disclosure.

Referring to FIG. 5, when the pixel pitch p as seen in FIG. 2 is 150 micrometers, and the distance d between the CF parallax layer 114 and the CF layer 110 is set to 60 micrometers and 180 micrometers. It shows that the distance d may influence the viewing angle (in which a user can see a whole color sub-pixel 200, and the aperture equals to 1). For example, if the distance d is 180 micrometers, the viewer can see a whole color sub-pixel 200 through a barrier unit 114A when the viewing angle is between 20-50 degrees (or −20 to −50 degrees), but if the distance d is 60 micrometers, the viewer can see a whole color sub-pixel 200 through a barrier unit 114A when the viewing angle is larger than 60 degrees (or less than −60 degrees).

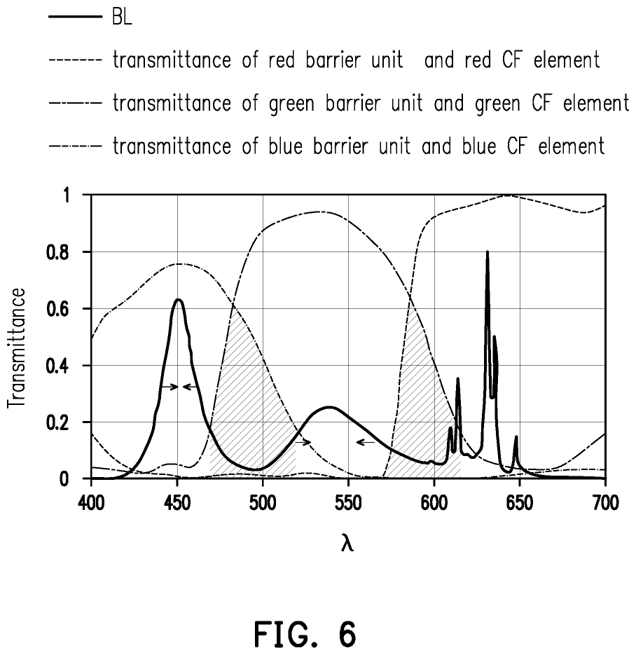

FIG. 6 is a drawing schematically illustrating the filtering effect of the color filter layer and the parallax barrier 114, according to an embodiment of the disclosure. In FIG. 6, the transmittance of the CF parallax layer 114 and color layer 110, and the spectrum of backlight unit 100 are shown. As shown in FIG. 6, each barrier unit 114A and CF element 1101 may have its own “transmittance-wavelength” relationship. For example, a green barrier unit 114A (or a green CF element G) has high transmittance in a range of 490 nm-570 nm, but the green barrier unit 114A (or the green CF element G) has low transmittance when the wavelength of light is less than 450 nm. Similarly, a red barrier unit 114A (or a red CF element 1101) and a blue barrier unit 114A (or a blue CF element 1101) respectively have their own “transmittance-wavelength” relationships, and there are some specific ranges (indicated as the shading region in FIG. 6) in which a certain portion of the light can go through barrier units 114A (or CF elements 1101) of two different colors. In other words, the barrier unit 114A of one color in the parallax barrier 90 may filter most of the light emitted from the color sub-pixel 200 of other colors, but when the wavelength of light emitted from the color sub-pixel 200 is in the aforementioned specific ranges, light leakage still occurs. However, if the spectrum width of the backlight is reduced, (in other words, the light intensity is more concentrated to the peak spectrum out of the aforementioned specific ranges), then less portion of light emitted from the color sub-pixels 200 is in the aforementioned specific ranges, and the light leakage may be reduced.

The filtering effect of the parallax barrier relates to the amount of light leakage. Theoretically, the transmittance of a light emitted from one color sub-pixel 200 to the barrier unit 114A of a different color may be less than 0.3 or may be even down to 0.05 in some embodiments.

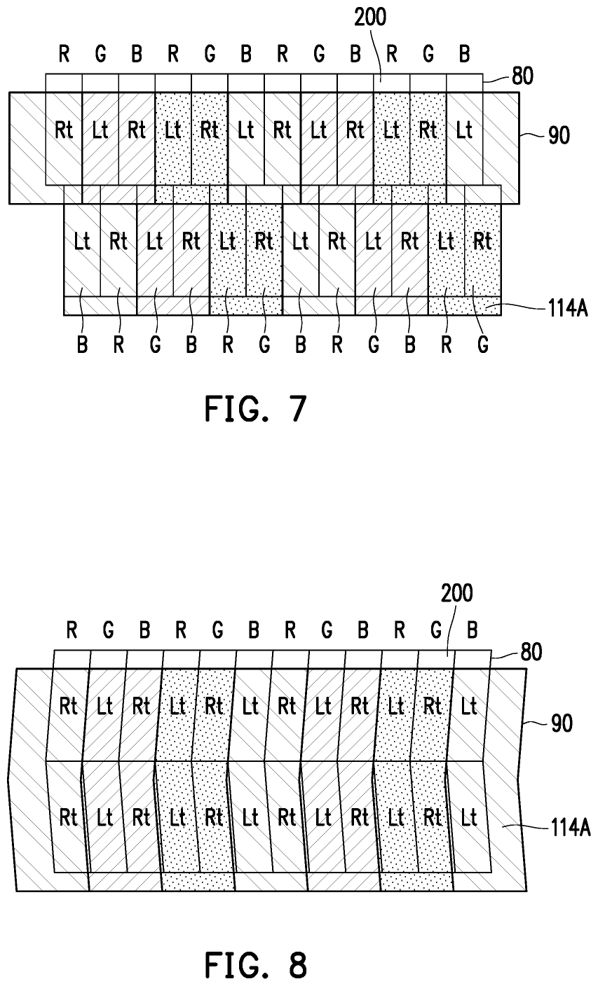

The arrangement of the sub-pixels of the display panel and the barrier units 114A of the parallax barrier in FIG. 2 may be further modified. Further embodiments are provided as the examples. FIG. 7 to FIG. 11 schematically illustrate the implementations of the parallax barrier with respect to the display panel, according to some embodiments of the disclosure.

Referring to FIG. 7, the positions of color sub-pixels 200a, 200b corresponding to the left-view image (Lt) or the right-view image (Rt) in one color sub-pixel row may be shifted. For example, in FIG. 7, the color sub-pixels 200, in the upper color sub-pixel row are shifted by a half of the color sub-pixel width than the color sub-pixels 200 in the lower color sub-pixel row. Meanwhile, the barrier units 114A corresponding to the color sub-pixels 200 in the upper color sub-pixel row are also shifted by a half of the color sub-pixel width.

Referring to FIG. 8, the shapes of color sub-pixels 200 for adjacent two color sub-pixel rows may be different. For example, in FIG. 8, the color sub-pixels in adjacent two color sub-pixel rows intersects by an included angle, and the shape of the barrier units 114A is accordingly changed. But the disclosure is not limited thereto. The rule for color designation to the barrier units 114A is the same as previously stated.

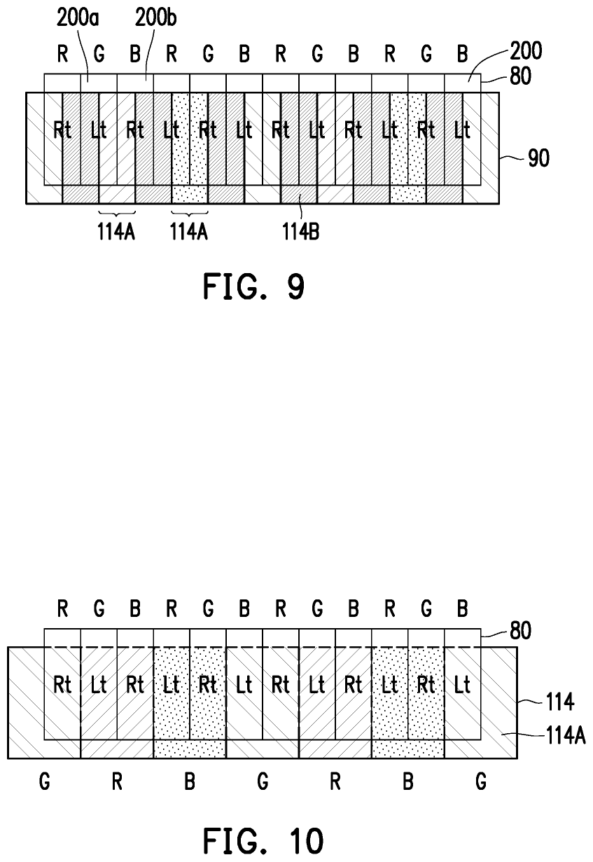

Referring to FIG. 9, in an embodiment, the parallax barrier 90 includes a black matrix 114B. In FIG. 9, a part of a black matrix 114B may be placed between two adjacent barrier units 114A. In an embodiment, the part of the black matrix 114B may overlap substantially 50% of the area of one color sub-pixel 200, but the disclosure is not limited thereto. In FIG. 9, The barrier units 114A overlaps two color sub-pixels 200a, 200b, but part of the color sub-pixels 200a, 200b is overlapped with the neighboring part of the black matrix 114B.

Referring to FIG. 10, in an embodiment, the CF parallax layer 114 may be in back of the display panel 80 instead of being in front of the display panel 80 in the foregoing embodiments.

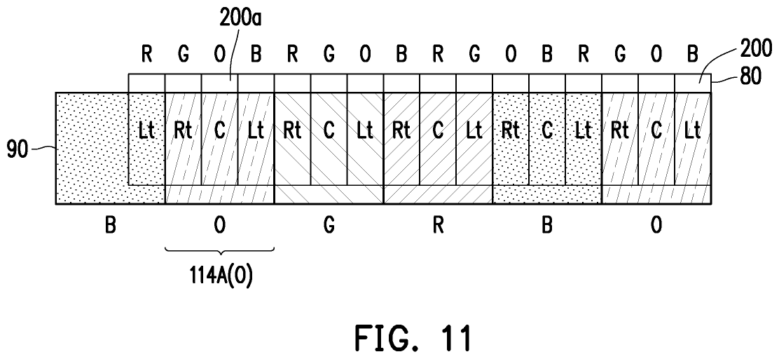

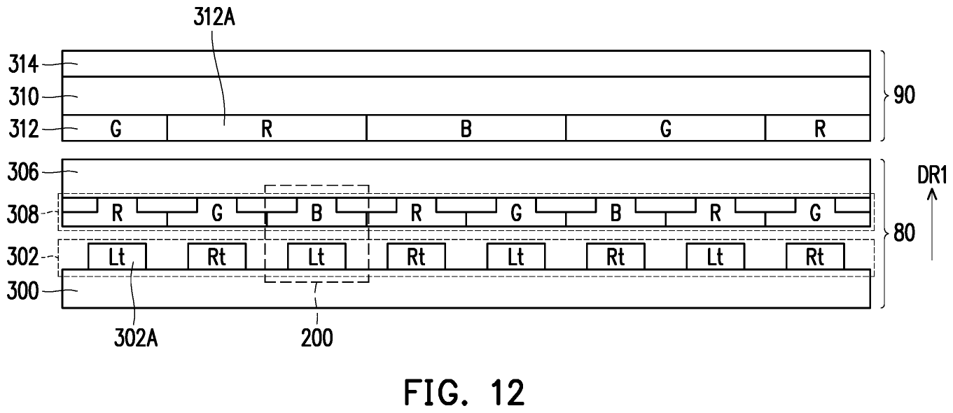

Referring to FIG. 11, the electronic device may display three-view image. In an embodiment, a third view image is added for a third user. The third-view image, as indicated by C is located between the left-view image Lt and the right-view image Rt. In the embodiment, a fourth orange color sub-pixel 200a (indicated by O) is added with a red color sub-pixel 200, a green color sub-pixel 200 and a blue color sub-pixel 200, but it should be noted that the fourth color is not limited to orange. The color sub-pixel 200 to display the third-view image C may be referred as the middle color sub-pixel, but the disclosure is not limited thereto.

In FIG. 11, the barrier unit 114A of the CF parallax layer 114 overlaps three color sub-pixels 200a, 200b and 200c in a normal direction of the display panel 80. The color of the barrier unit 114A is the same as the color of the middle color sub-pixel 200b.

As previously stated, the embodiments as provided may have suitable combination therebetween. The disclosure is not just limited to the embodiments as provided.

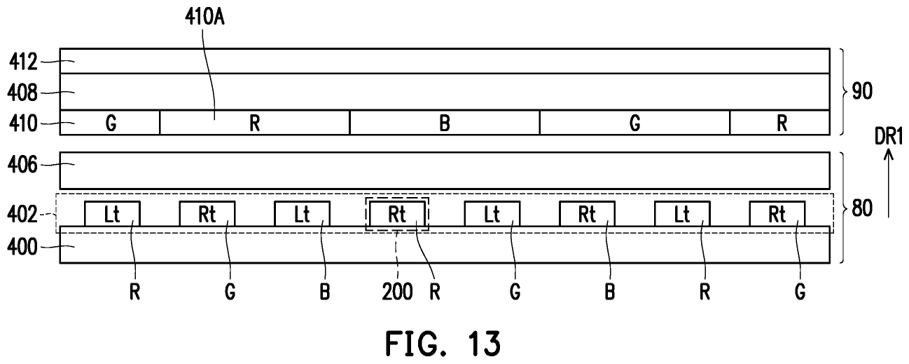

Further to the display panel based on the LED panel, the CF parallax layer 114 may be applied as well. FIG. 12 to FIG. 13 schematically illustrate structures of the electronic device, according to embodiments of the disclosure.

Referring to FIG. 12, the display panel 80 is an organic LED (OLED) panel in the embodiment, the display panel 80 includes the sub-pixel layer 302 with OLED 302A on a substrate 300 to display the left-view image Lt or the right-view image Rt. However, a CF layer 308 formed on another substrate 306 is provided to produce the designated color. One CF element in the CF layer 308 and one OLED 302A form one color sub-pixel 200. It should be noted that in some embodiments, the display panel 80 may be a mini-LED panel or a micro-LED panel. In other words, the sub-pixel 302A in the sub-pixel layer 302 is not limited to OLED, the sub-pixel layer may include mini-LEDs, micro-LEDs or other light emitting elements.

The CF parallax layer 312 includes barrier units 312A with the designated color. The function of the CF parallax layer 312 may be similar to previous embodiments.

Referring to FIG. 13, another embodiment is disclosed. In FIG. 13, a color sub-pixel 200 may be a micro-LED to emit color light directly, and the CF layer is not needed and the CF layer may be replaced by a substrate 406. It should be noted that the color sub-pixel 200 is not limited to color micro-LED, in some embodiments, the color sub-pixel 200 is a color OLED, a color mini-LED or other light emitting element.

In an embodiment, a parallax barrier 90 includes a CF parallax layer 410 which is disposed on another substrate 408. A polarizer layer 412 may also be disposed on the opposite side of the substrate 408 but not the limitation. In an embodiment, a CF parallax layer 410 includes barrier units 410A with the designated color. The function of the CF parallax layer 410 may be similar to previous embodiments.

The disclosure provides an electronic device in which the parallax barrier includes a CF parallax layer. The barrier units of the CF parallax layer are designated with proper colors. A barrier unit overlaps at least two adjacent sub-pixels in a normal direction of the display panel, and the barrier unit may filter the lights of different colors and keep the light of the same color to transmit.

It will be apparent to those skilled in the art that various modifications, combinations and variations can be made to the structure of the present disclosure without departing from the scope or spirit of the disclosure. In view of the foregoing, it is intended that the present disclosure covers combinations, modifications and variations of this disclosure are still in the scope of the following claims and their equivalents.

1. An electronic device, comprising:
a display panel, comprising a plurality of color sub-pixels, wherein the plurality of color sub-pixels comprise a color sub-pixel of a first color, a color sub-pixel of a second color, a color sub-pixel of a third color; and
a parallax barrier, overlapping the display panel, wherein the parallax barrier comprises a color filter parallax layer, a polarizer layer disposed on the color filter parallax layer, and a substrate disposed between the polarizer layer and the color filter parallax layer, the color filter parallax layer comprises a plurality of barrier units, the plurality of the barrier units comprise a barrier unit of a first color, and the barrier unit of the first color overlaps the color sub-pixel of the second color and the color sub-pixel of the third color in a top view.

2. The electronic device of claim 1, wherein the display panel comprises a color filter (CF) layer and a sub-pixel layer, wherein the CF layer comprises a plurality of color filter (CF) elements, the sub-pixel layer comprises a plurality of sub-pixels.

3. The electronic device of claim 2, wherein the display panel comprises a first substrate, and the sub-pixel layer is disposed on the first substrate.

4. The electronic device of claim 2, wherein the display panel comprises a second substrate, and the CF layer is disposed on the second substrate.

5. The electronic device of claim 2, wherein the display panel comprises a first substrate, and the CF layer and the sub-pixel layer are disposed on the first substrate.

6. The electronic device of claim 2, wherein one of the plurality of the color sub-pixels comprises one of the plurality of color filter (CF) elements and one of the plurality of sub-pixels.

7. The electronic device of claim 2, wherein the sub-pixel layer comprises a sub-pixel row, and the plurality of sub-pixels arranged in the sub-pixel row display a first-view image and a second-view image.

8. The electronic device of claim 2, wherein a distance between the color filter parallax layer and the CF layer is between 60 micrometers and 180 micrometers.

9. The electronic device of claim 1, wherein the display panel comprises a plurality of color sub-pixels in a first color sub-pixel row and a plurality of color sub-pixels in a second color sub-pixel row adjacent to the first color sub-pixel row, and the plurality of color sub-pixels in the second color sub-pixel row are shifted.

10. The electronic device of claim 1, wherein the display panel comprises a plurality of color sub-pixels in a first color sub-pixel row and a plurality of color sub-pixels in a second color sub-pixel row adjacent to the first color sub-pixel row, wherein one of the plurality of color sub-pixels in the first color sub-pixel row and one of the plurality of color sub-pixels in the second color sub-pixel row intersect by an included angle.

11. The electronic device of claim 1, wherein the parallax barrier comprises a black matrix, and a part of the black matrix is placed between one of the plurality of barrier units and an adjacent one of the plurality of barrier units.

12. The electronic device of claim 1, wherein the parallax barrier overlaps the display panel in a normal direction of the display panel.

13. The electronic device of claim 1, wherein the display panel is a liquid crystal display panel.

14. The electronic device of claim 1, wherein the display panel is an organic light-emitting diode panel.

15. The electronic device of claim 14, wherein the display panel comprises a color filter layer.

16. The electronic device of claim 1, wherein the display panel is a micro light emitting diode panel.

17. The electronic device of claim 16, wherein the display panel comprises a color filter layer.

18. An electronic device, comprising:
a display panel, comprising a plurality of color sub-pixels, wherein the plurality of color sub-pixels comprise a color sub-pixel of a first color, a color sub-pixel of a second color, a color sub-pixel of a third color, and a color sub-pixel of a fourth color; and
a parallax barrier, overlapping the display panel, wherein the parallax barrier comprises a color filter parallax layer, a polarizer layer disposed on the color filter parallax layer, and a substrate disposed between the polarizer layer and the color filter parallax layer, the color filter parallax layer comprises a plurality of barrier units, the plurality of barrier units comprise a barrier unit of a fourth color, and the barrier unit of the fourth color overlaps the color sub-pixel of the second color, the color sub-pixel of the third color and the color sub-pixel of the fourth color in a top view.

19. The electronic device of claim 18, wherein the color sub-pixel of the fourth color is located between the color sub-pixel of the second color and the color sub-pixel of the third color.

20. The electronic device of claim 18, wherein the fourth color is orange.
